(19) United States
(12) Patent Application Publication
(10) Pub. No.: US 2025/0281962 A1
(43) Pub. Date: Sep. 11, 2025

(54) METHOD FOR SHELL RIGHT ANGLE BENDING PROCESS

(71) Applicant: SHENZHEN FUTAIXIN TECHNOLOGY CO., LTD, SHENZHEN CITY (CN)

(72) Inventor: XIAOJIE ZHENG, SHENZHEN CITY (CN)

(21) Appl. No.: 18/776,190

(22) Filed: Jul. 17, 2024

(30) Foreign Application Priority Data
Mar. 8, 2024 (CN) 202410268716.3

(51) Int. Cl. B21D 28/26

(52) U.S. Cl. CPC B21D 28/26

(57) ABSTRACT

A method for shell right angle bending process is provided, which belongs to the field of shell processing. The method includes cutting an aluminum alloy plate into a primary blank body, arranging an avoidance notch on an outside of the primary blank body, extruding downward the aluminum alloy to form a side bending part and a hinge bending part on the outside of the primary blank body, applying a pressure on the side bending part toward the hinge bending part to make the side bending part and the hinge bending part vertically connected, applying a pressure on a top of the side bending part and a top of the hinge bending part toward a central axis of the primary blank body, then applying a downward pressure to the top of the side bending part and make it parallel with a top of the primary blank body.

### FIELD OF THE DISCLOSURE

The present disclosure relates to a field of shell processing, and more particularly to a method for shell right angle bending process.

### BACKGROUND OF THE DISCLOSURE

With the development of society and the continuous development of communication technology, the application of laptop becomes more and more common, and the requirements for laptop are accordingly increasing. Most of the conventional laptop shells are made of the aluminum material, which is usually made using a whole slab of aluminum alloy by a CNC process, thereby resulting in higher manufacturing costs. Further, the shell of laptop operation panel is composed of an upper shell and a lower shell. In the manufacturing process, the outside of the upper shell is one-step molded through a bending process. However, the bending part often has wrinkles and cracks and cannot satisfy the high standard of consumer demands. Moreover, due to disadvantages of bending technology, the bending connection part being round angle shape after bending, which make the product unattractive. Further, the aluminum upper shell of the laptop is also prone to occur cracking and stacking problems when bending the assembly side of the hinge at right angles.

### SUMMARY OF THE DISCLOSURE

The problem to be solved by the present disclosure is that the upper shell of laptop operation panel is one-step molded through a bending process, causing that the bending part often has wrinkles and cracks and cannot satisfy the high standard of consumer demands. Moreover, due to disadvantages of bending technology, the bending connection part being round angle shape after bending, which make the product unattractive. Further, the aluminum upper shell of the laptop is also prone to occur cracking and stacking problems when bending the assembly side of the hinge at right angles. In response to the above-referenced technical inadequacies, the present disclosure provides a method for shell right angle bending process.

In order to solve the above-mentioned problems, one of the technical aspects adopted by the present disclosure is to provide a method for shell right angle bending process includes the following steps:
S1: cutting, cutting an aluminum alloy plate into a primary blank body based on a size and a shape in need. An avoidance notch is arranged on an outside of the primary blank body;
S2: stretching and protruding, extruding downward the aluminum alloy that is cut, such that a bending part is formed on the outside of the primary blank body. The bending part has a side bending part and a hinge bending part, and the avoidance notch is arranged between side bending part and the hinge bending part;
S3: shaping, applying one pressure on the side bending part toward the hinge bending part, and limiting position at the hinge bending part to limit bending at the hinge bending part. Under the pressure the side bending part extrudes toward the hinge bending part, and a connection between the side bending part and the hinge bending part is deformed to make the side bending part and the hinge bending part vertically connected to each other;
S4: back-extruding, applying another pressure on the side bending part toward a central axis of the primary blank body. Under the another pressure, the side bending part extrudes toward the central axis of the primary blank body, a connection between the side bending part and the primary blank body is deformed to make the side bending part and the primary blank body vertically connected to each other;
S5: first necking, correspondingly arranging a necking part on a top of the side bending part and a top of the hinge bending part, correspondingly applying a further pressure on the top of the side bending part and the top of the hinge bending part toward the central axis of the primary blank body, then stop applying the further pressure while each of the top of the side bending part and the top of the hinge bending part is tilted 30 degrees to 60 degrees toward the center of the primary blank body;
S6: second necking, applying a downward pressure to the necking part to make the necking part bends downward until being parallel with a top surface of the primary blank body.

Preferably, in S3, a bending reserved portion is arranged on the outside of the primary blank body, the bending reserved portion extrudes toward the central axis of the primary blank body with the side bending part, and the side bending part compresses the bending reserved portion.

Preferably, a width of the bending reserved portion is 10 mm to 15 mm.

Preferably, the aluminum alloy is a five-series aluminum alloy.

Preferably, in S2, the top surface of the primary blank body is concavely shaped with a groove body while extruding downward the aluminum alloy that is cut.

Preferably, the primary blank body includes a square aluminum plate, and a side of the square aluminum plate is provided with an assembly groove.

Preferably, the hinge bending part is arranged at the side of the square aluminum plate provided with the assembly groove.

Preferably, a hardness of the aluminum alloy is 65 HB to 75 HB.

Preferably, n S2, an angle between the side bending part and the hinge bending part is R=1 mm to 1.5 mm.

Preferably, in S4, when the side bending part extrudes toward the hinge bending part, as size of the avoidance notch continuously is adjusted so as to prevent the side bending part from overlapping with the hinge bending part.

The beneficial effects of the subject matter provided by the present disclosure is that:
1. In the present disclosure, the aluminum alloy plate is cut into the primary blank body based on the size and the shape in need and the avoidance notch is arranged on the outside of the primary blank body. The avoidance notch can prevent the side bending part and the hinge bending part from extruding and overlapping with each other while forming the side bending part and the hinge bending part, and the avoidance notch can be continuously expanded while forming the side bending part and the hinge bending part. Accordingly, the avoidance notch can be arranged relatively small before forming the side bending part and the hinge bending part. When the avoidance notch form at the side bending part and the hinge bending part, if the avoidance notch is too small, the avoidance notch can be further expanded to make the size of the avoidance notch appropriate.
2. By virtue of the ductility of the aluminum alloy, the bending portion is formed on the outside of the primary blank body without being damaged, and the connection between the side bending part and the hinge bending part is deformed to make the side bending part and the hinge bending part vertically connected to each other. The connecting part between the side bending part and the primary blank body can be gradually deformed to make the side bending part and the primary blank body vertically connected to each other. The top of the side bending part bends downward until being parallel with the top surface of the primary blank body.

By processing the outside of the aluminum alloy laptop shell, a vertical connection is formed between the side bending part and the primary blank body, and both of the top of the side bending part and the top of the hinge bending part are formed with the necking part parallel to the primary blank body, thereby saving the manufacturing cost and the shell of the laptop is more attractive, and the overall strength is also increased.

### BRIEF DESCRIPTION OF THE DRAWINGS

In order to more clearly illustrate the embodiments of the present disclosure or the technical solutions in the prior art, the present disclosure will be further described with reference to the accompanying drawings and embodiments, in which the drawings in the following description are only some embodiments of the present disclosure, and other drawings may be obtained by those skilled in the art without inventive effort:

FIG. 1 is a schematic axonometric view of aluminum alloy that is cut according to the present disclosure;

FIG. 2 is a schematic enlarged view of part C of FIG. 1 according to the present disclosure;

FIG. 3 is a schematic axonometric view showing being after stretching and protruding according to the present disclosure;

FIG. 4 is a schematic enlarged view of part D of FIG. 3 according to the present disclosure;

FIG. 5 is a schematic axonometric view showing being after shaping according to the present disclosure;

FIG. 6 is a schematic enlarged view of part E of FIG. 5 according to the present disclosure;

FIG. 7 is a schematic axonometric view showing a necking at extrusion of 45 degrees according to the present disclosure;

FIG. 8 is a schematic enlarged view of part A of FIG. 7 according to the present disclosure;

FIG. 9 is a schematic axonometric view showing being after the necking according to the present disclosure;

FIG. 10 is a schematic enlarged view of part B of FIG. 9 according to the present disclosure;

FIG. 11 is a schematic axonometric view showing being after stamping keyboard hole according to the present disclosure;

FIG. 12 is a schematic axonometric view showing being after stamping through holes at a side bending part according to the present disclosure.

### DETAILED DESCRIPTION OF THE EXEMPLARY EMBODIMENTS

To make the objects, technical solutions and advantages of the embodiments of the present disclosure clearer, the technical solutions of the present disclosure will be clearly and completely described below with reference to the accompanying drawings, and it is apparent that the described embodiments are some, but not all embodiments of the present disclosure. All other embodiments, which can be derived by a person skilled in the art from the embodiments given herein without making any creative effort, shall fall within the protection scope of the present disclosure.

In the description of the embodiments of the present disclosure, it is also to be noted that, unless otherwise expressly specified and defined, terms such as “connect”, “interconnect” and other terms shall be understood in a broad way. For example, unless otherwise expressly defined, may be a fixed connection, detachable connection, or integral connection; it may be a mechanical connection, an electrical connection; it may be direct connection, or indirect connection through an intermedium; and it may be an internal connection of two components or an interaction between two components. For those of ordinary skill in the art, the specific meaning of the above terms in the context of the present disclosure can be understood on a case-by-case basis.

In the description of the embodiments of the present disclosure, unless otherwise explicitly specified or limited, if a first member is described to be on or under a second member, there may be direct contact between the first and second members, or indirect contact between the first and second members through an intermedium. Besides, if a first member is described to be above a second member, it may mean that the first member is rightly above or diagonally above the second member, or that the first member is horizontally higher above the second member. If a first member is described to be below a second member, it may mean that the first member is right below or diagonally below the second member, or that the first member is horizontally lower than the second member.

In the description of the present disclosure, the description referring to the terms “one embodiment”, “some embodiments”, “an example”, “a specific example” or “some examples” means that the specific features, structures, materials or characteristics described in connection with this embodiment or example are included in at least one embodiment or example of the present disclosure. In this specification, the schematic expressions of the above terms do not necessarily refer to the same embodiment or example. Furthermore, the specific features, structures, materials or characteristics described may be combined in any one or more embodiments or examples in a suitable manner. In addition, under the condition of no mutual contradiction, those skilled in the art may combine and integrate different embodiments or examples and the features of the different embodiments or examples, which are described in the description.

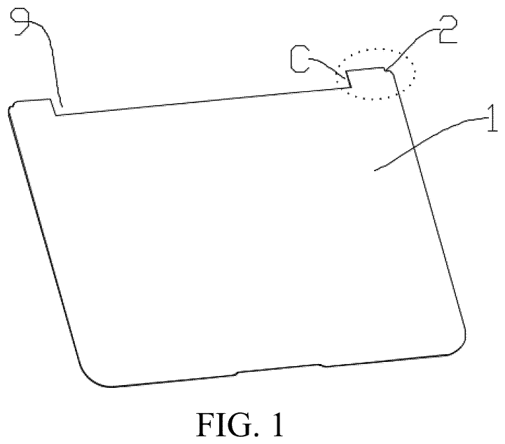

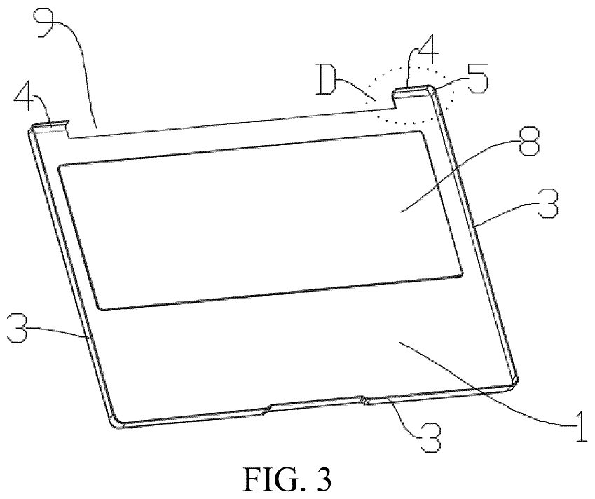

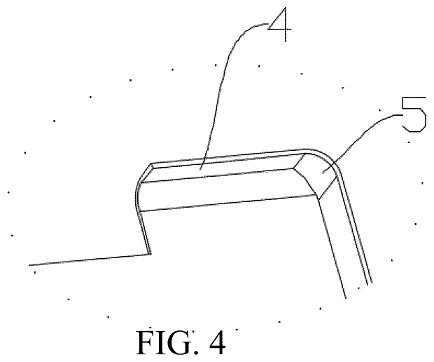

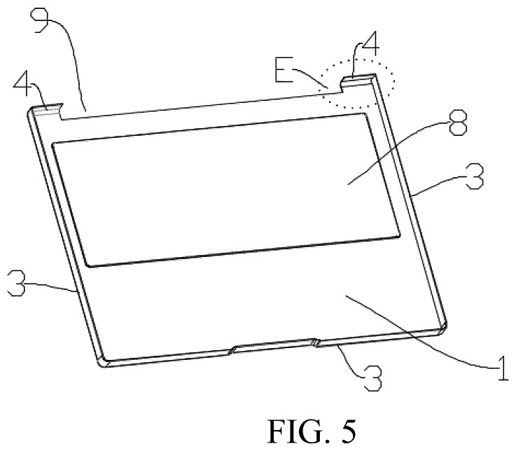

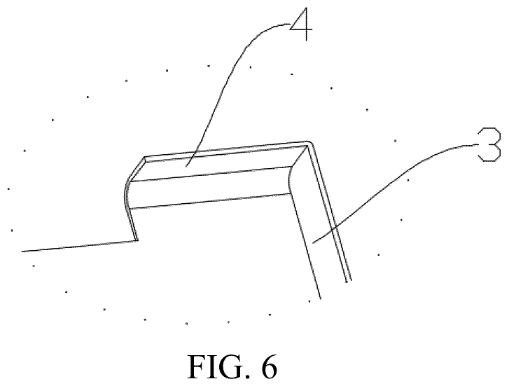

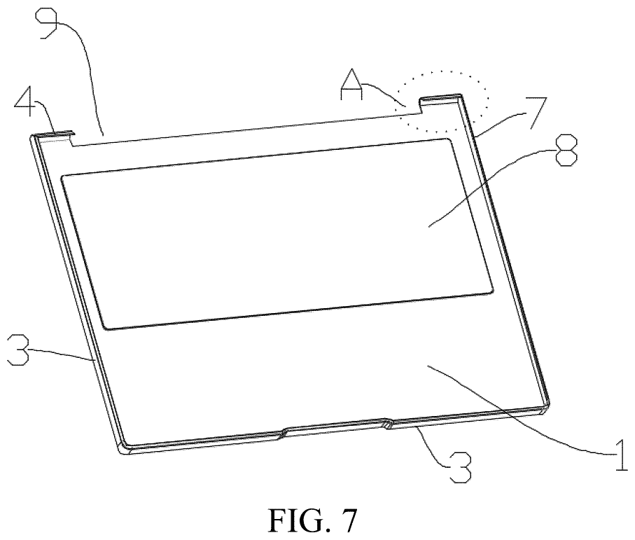

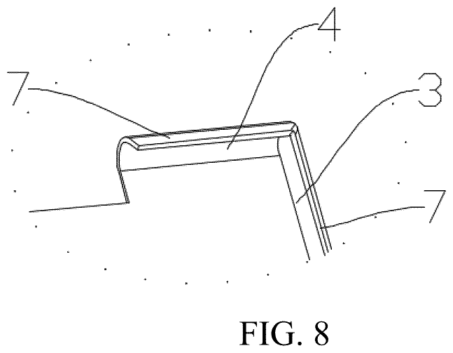

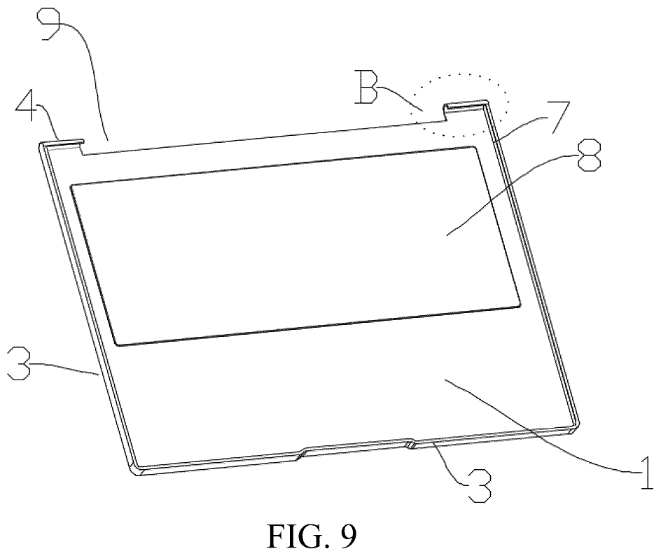

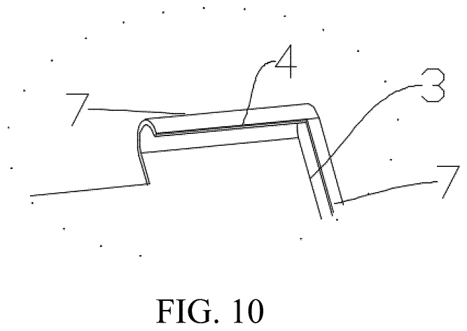

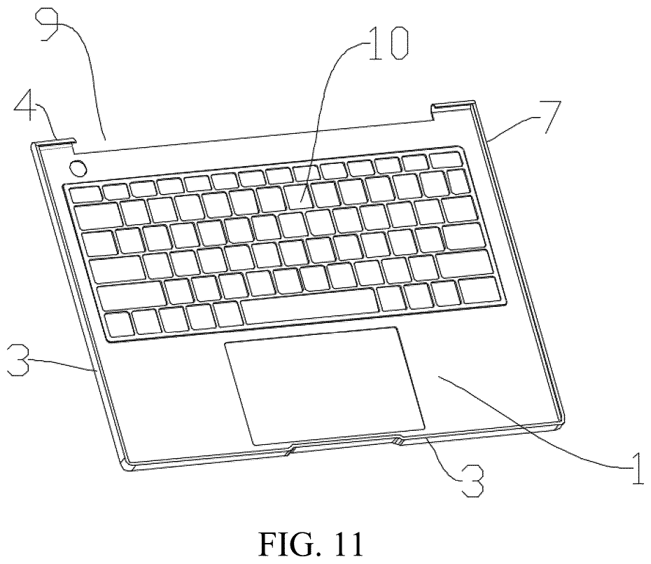

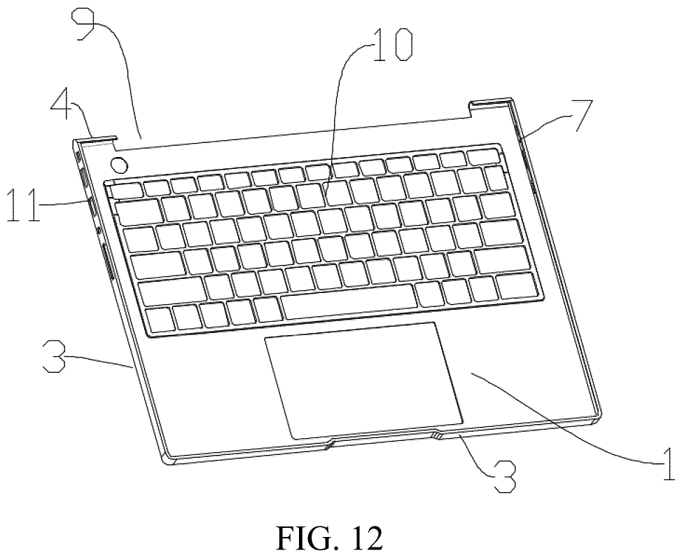

As shown in FIGS. 1 to 12, the embodiments of the present disclosure relates to a method for shell right angle bending process, including the following steps:
S1: cutting, cutting aluminum alloy into a primary blank body 1 based on a size and a shape in need. An avoidance notch 2 is arranged on an outside of the primary blank body 1;
S2: stretching and protruding, extruding downward the aluminum alloy that is cut, such that a bending part is formed on the outside of the primary blank body 1. The bending part has a side bending part 3 and a hinge bending part 4, and the hinge bending part 4 can be provided in subsequent assembly to install the laptop hinge in the hinge bending part 4. A connection between the side bending part 3 and the primary blank body 1 is a first round angle, a connection between the side bending part 3 and the hinge bending part 4 is a second round angle 6, and the avoidance notch 2 is arranged between the side bending part 3 and the hinge bending part 4. Further, the aluminum alloy that is cut can be stamped using a stamping mold. Since the aluminum alloy has better ductility, the side bending part 3 and the hinge bending part 4 can be formed more effectively. The stamping mold includes a lower mold and an upper mold, the aluminum alloy is disposed on the lower mold and the upper mold can extrude the aluminum alloy. When the upper mold extrudes the aluminum alloy downward, the primary blank body 1 removes downward and the outside is bent to form the side bending part 3 and the hinge bending part 4.
S3: shaping, applying one pressure on the side bending part 3 toward the hinge bending part 4, and a limiting device is arranged at the hinge bending part 4 to limit bending at the hinge bending part 4. Under the one pressure, the side bending part 3 extrudes toward the hinge bending part 4. At this time, the connection between the side bending part 3 and the hinge bending part 4 in S2 is deformed to make the side bending part 3 and the hinge bending part 4 vertically connected to each other. Accordingly, the connection strength and hardness between the side bending part 3 and the hinge bending part 4 is enhanced. At this time, the avoidance notch 2 can be repaired by repairing.
S4: back-extruding, applying another pressure on the side bending part 3 toward a central axis of the primary blank body 1. Under the another pressure, the side bending part 3 extrudes toward the central axis of the primary blank body 1, the connection between the side bending part 3 and the primary blank body 1 is deformed to make the side bending part 3 and the primary blank body 1 vertically connected to each other. Because the side bending part 3 extrudes the primary blank body 1, when the vertical connection is formed between the side bending part 3 and the primary blank body 1, a connection strength and hardness between the side bending part 3 and the primary blank body 1 is enhanced and a corrosion resistant property of the aluminum alloy is improved. Surface oxide scale and thermal cracks can be removed form the aluminum alloy during the extrusion process, making the aluminum surface smoother, brighter and more corrosion-resistant. During the back-extruding process, the metal blank is heated to a higher temperature and then extruded through the die. Compared with the conventional cutting processing, the back-extruding process can reduce waste and save material costs. Further, To fix the primary blank body 1, an extrusion mold can be used to act on the side bending part 3, such that the side bending part 3 can be evenly stressed, thereby preventing the side bending part 3 from deforming when moving toward a center point of the primary blank body 1. The extrusion mold includes a push plate, an area of the push plate is equal to a side area of the side bending part 3. Each of a top and a bottom of the push plate is provided with a positioning part, and the positioning parts can be used to position the push plate on the side bending part 3.
S5: first necking, correspondingly arranging a necking part 7 on a top of the side bending part 3 and a top of the hinge bending part 4, applying a pressure on the tip of the side bending part 3 and the hinge bending part 4 toward the central axis of the primary blank body 1, then stop applying pressure while the top of the side bending part 3 and the hinge bending part 4 is tilted 30-60 degrees toward the center of the primary blank body 1. Preferably, stop applying pressure while the top of the side bending part 3 and the hinge bending part 4 is tilted 45 degrees toward the center of the primary blank body 1.
S6: second necking, applying a downward pressure to the necking part 7 to make the necking part 7 bend downward until being parallel with a top surface of the primary blank body 1.

In the step of S3, a bending reserved portion is arranged on the outside of the primary blank body 1, the bending reserved portion extrudes toward the central axis of the primary blank body 1 with the side bending part 3, and the side bending part 3 compresses the bending reserved portion, such that the bending reserved portion is tightened and the strength is increased at the same time. Further, by setting the appropriate reserved portion in advance, a bending angle and a bending position can be controlled more accurately, thereby improving accuracy and consistency of a final product. The design of the reserved portion can effectively reduce stress concentration during the bending process and avoid cracks or fractures in the material at the bending point.

In the present embodiment, a width of the bending reserved portion (not show in the figures) is 10 mm to 15 mm.

In the present embodiment, the aluminum alloy is a five-series aluminum alloy. The five-series aluminum alloy has a good corrosion resistant property and a high strength. The five-series aluminum alloy has medium strength under cold working, which is suitable for applications that require a certain amount of strength but good formability. The specific model of the aluminum alloy can be 5052 or 5B52.

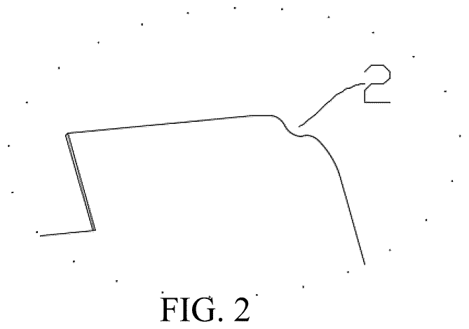

Referring to FIG. 2 to FIG. 9, in the step of S2, the top surface of the primary blank body 1 is concavely shaped with a groove body 8 while extruding downward the aluminum alloy that is cut. The groove body 8 can be stamped to form a plurality of keyboard hole in the groove body 8 by using a stamping mold in the subsequent process.

Referring to FIG. 1 to FIG. 9, the primary blank body 1 includes a square aluminum plate, and a side of the square aluminum plate is provided with an assembly groove 9. The existence of the assembly groove 9 may facilitate the combined connection of the laptop shell and the laptop display screen.

In the present embodiment, the hinge bending part 4 is arranged at the side of the square aluminum plate equipped with the assembly groove 9.

In the present embodiment, a hardness of the aluminum alloy is 65 HB to 75 HB, and preferably 70 HB.

In the present embodiment, the second round angle 6 is R=1 mm to 1.5 mm, and preferably 1 mm.

Referring to FIG. 1 to FIG. 9, in the step of S4, when the side bending part 3 extrudes toward the hinge bending part 4, a size of the avoidance notch 2 is continuously adjusted so as to prevent the side bending part 3 from overlapping with the hinge bending part 4. Further, the avoidance notch 2 may be arranged relatively small before forming the side bending part 3 and the hinge bending part 4. When the avoidance notch 2 is formed at the side bending part 3 and the hinge bending part 4, if the avoidance notch 2 is too small, the avoidance notch 2 is further expanded to make the size of the avoidance notch 2 appropriate.

Moreover, in the subsequent processing of the present disclosure, a plurality of through holes are formed on the side bending part 3.

It is to be understood that those skilled in the art will be able to make modifications and changes in accordance with the above description, and all such modifications and variations are intended to be included within the scope of the appended claims.

What is claimed is:

1. A method for shell right angle bending process, comprising:
S1: cutting, cutting an aluminum alloy plate into a primary blank body (1) based on a size and a shape in need, wherein an avoidance notch (2) is arranged on an outside of the primary blank body (1);
S2: stretching and protruding, extruding downward the aluminum alloy plate that is cut, such that a bending part is formed on the outside of the primary blank body (1), wherein the bending part has a side bending part (3) and a hinge bending part (4), and the avoidance notch (2) is arranged between side bending part (3) and the hinge bending part (4);
S3: shaping, applying one pressure on the side bending part (3) toward the hinge bending part (4), and limiting position at the hinge bending part (4) to limit bending at the hinge bending part (4); wherein, under the one pressure, the side bending part (3) extrudes toward the hinge bending part (4), and a connection between the side bending part (3) and the hinge bending part (4) is deformed to make the side bending part (3) and the hinge bending part (4) vertically connected to each other;
S4: back-extruding, applying another pressure on the side bending part (3) toward a central axis of the primary blank body (1); under the another pressure, the side bending part (3) extrudes toward the central axis of the primary blank body (1), a connection between the side bending part (3) and the primary blank body (1) is deformed to make the side bending part (3) and the primary blank body (1) vertically connected to each other;
S5: first necking, correspondingly arranging a necking part (7) on a top of the side bending part (3) and a top of the hinge bending part (4), correspondingly applying a further pressure on the top of the side bending part (3) and the top of the hinge bending part (4) toward the central axis of the primary blank body (1), then stop applying the further pressure while each of the top of the side bending part (3) and the top of the hinge bending part (4) is tilted 30 degrees to 60 degrees toward the center of the primary blank body (1);
S6: second necking, applying a downward pressure to the necking part (7) to make the necking part (7) bend downward until being parallel with a top surface of the primary blank body (1).

2. The method for shell right angle bending process according to claim 1, wherein in S3, a bending reserved portion is arranged on the outside of the primary blank body (1), the bending reserved portion extrudes toward the central axis of the primary blank body (1) with the side bending part (3), and the side bending part (3) compresses the bending reserved portion.

3. The method for shell right angle bending process according to claim 2, wherein a width of the bending reserved portion is 10 mm to 15 mm.

4. The method for shell right angle bending process according to claim 1, wherein the aluminum alloy is a five-series aluminum alloy.

5. The method for shell right angle bending process according to claim 1, wherein in S2, the top surface of the primary blank body (1) is concavely shaped with a groove body (8) while extruding downward the aluminum alloy that is cut.

6. The method for shell right angle bending process according to claim 1, wherein the primary blank body (1) includes a square aluminum plate, and a side of the square aluminum plate is provided with an assembly groove (9).

7. The method for shell right angle bending process according to claim 6, wherein the hinge bending part (4) is arranged at the side of the square aluminum plate provided with the assembly groove (9).

8. The method for shell right angle bending process according to claim 6, wherein a hardness of the aluminum alloy is 65 HB to 75 HB.

9. The method for shell right angle bending process according to claim 1, wherein in S2, an angle between the side bending part (3) and the hinge bending part (4) is R=1 mm to 1.5 mm.

10. The method for shell right angle bending process according to claim 1, wherein in S4, when the side bending part (3) extrudes toward the hinge bending part (4), a size of the avoidance notch (2) is continuously adjusted so as to prevent the side bending part (3) from overlapping with the hinge bending part (4).

11. The method for shell right angle bending process according to claim 2, wherein in S4, when the side bending part (3) extrudes toward the hinge bending part (4), a size of the avoidance notch (2) is continuously adjusted so as to prevent the side bending part (3) from overlapping with the hinge bending part (4).

12. The method for shell right angle bending process according to claim 3, wherein in S4, when the side bending part (3) extrudes toward the hinge bending part (4), a size of the avoidance notch (2) is continuously adjusted so as to prevent the side bending part (3) from overlapping with the hinge bending part (4).

13. The method for shell right angle bending process according to claim 4, wherein in S4, when the side bending part (3) extrudes toward the hinge bending part (4), a size of the avoidance notch (2) is continuously adjusted so as to prevent the side bending part (3) from overlapping with the hinge bending part (4).

14. The method for shell right angle bending process according to claim 5, wherein in S4, when the side bending part (3) extrudes toward the hinge bending part (4), a size of the avoidance notch (2) is continuously adjusted so as to prevent the side bending part (3) from overlapping with the hinge bending part (4).

15. The method for shell right angle bending process according to claim 6, wherein in S4, when the side bending part (3) extrudes toward the hinge bending part (4), a size of the avoidance notch (2) is continuously adjusted so as to prevent the side bending part (3) from overlapping with the hinge bending part (4).

16. The method for shell right angle bending process according to claim 7, wherein in S4, when the side bending part (3) extrudes toward the hinge bending part (4), a size of the avoidance notch (2) is continuously adjusted so as to prevent the side bending part (3) from overlapping with the hinge bending part (4).

17. The method for shell right angle bending process according to claim 8, wherein in S4, when the side bending part (3) extrudes toward the hinge bending part (4), a size of the avoidance notch (2) is continuously adjusted so as to prevent the side bending part (3) from overlapping with the hinge bending part (4).

18. The method for shell right angle bending process according to claim 9, wherein in S4, when the side bending part (3) extrudes toward the hinge bending part (4), a size of the avoidance notch (2) is continuously adjusted so as to prevent the side bending part (3) from overlapping with the hinge bending part (4).
